(19) United States
(12) Patent Application Publication
(10) Pub. No.: US 2009/0294876 A1
(43) Pub. Date: Dec. 3, 2009

(54) METHOD FOR DEPOSITION OF AN ULTRA-THIN ELECTROPOSITIVE METAL-CONTAINING CAP LAYER

(75) Inventors: Supratik Guha, Chappaqua, NY (US); Fenton R. McFeely, Ossining, NY (US); Vijay Narayanan, New York, NY (US); Vamsi K. Paruchuri, New York, NY (US); John J. Yurkas, Stamford, CT (US)

Correspondence Address: SCULLY, SCOTT, MURPHY & PRESSER, P.C., 400 GARDEN CITY PLAZA, SUITE 300, GARDEN CITY, NY, 11530, US

(73) Assignee: INTERNATIONAL BUSINESS MACHINES CORPORATION, Armonk, NY (US)

(21) Appl. No.: 12/541,241

(22) Filed: Aug. 14, 2009

Related U.S. Application Data
(62) Division of application No. 11/773,160, filed on Jul. 3, 2007.

(51) Int. Cl. H01L 29/78

(52) U.S. Cl. 257/410; 257/E29.255

(57) ABSTRACT

A method of forming an electropositive metal-containing capping layer atop a stack of a high k gate dielectric/interfacial layer that avoids chemically and physically altering the high k gate dielectric and the interfacial layer is provided. The method includes chemical vapor deposition of an electropositive metal-containing precursor at a temperature that is about 400° C. or less. The present invention also provides semiconductor structures such as, for example, MOSCAPs and MOSFETs, that include a chemical vapor deposited electropositive metal-containing capping layer atop a stack of a high k gate dielectric and an interfacial layer. The presence of the CVD electropositive metal-containing capping layer does not physically or chemically alter the high k gate dielectric and the interfacial layer.

### CROSS-REFERENCE TO RELATED APPLICATIONS

This application is a divisional of U.S. patent application Ser. No. 11/773,160, filed Jul. 3, 2007.

### BACKGROUND

The present invention generally relates to a semiconductor structure, and more particularly to a semiconductor structure including an ultra-thin electropositive metal-containing cap layer located atop a high k gate dielectric for tuning the threshold voltage via electrostatic control of a field effect transistor, especially an n-type field effect transistor. The present invention also provides a method of forming such a structure including a method for the deposition of the electropositive metal-containing cap layer.

In standard silicon complementary metal oxide semiconductor (CMOS) technology, n-type field effect transistors (nFET) use an As (or other donor) doped n-type polysilicon layer as a gate electrode that is deposited on top of a silicon dioxide or silicon oxynitride gate dielectric layer. The gate voltage is applied through this polysilicon layer to create an inversion channel in the p-type silicon underneath the gate oxide layer.

In future technology, silicon dioxide or silicon oxynitride dielectrics will be replaced with a gate material that has a higher dielectric constant. These materials are known as “high k” materials with the term “high k” denoting an insulating material whose dielectric constant is greater than about 4.0, preferably greater than about 7.0. The dielectric constants mentioned herein are relative to a vacuum unless otherwise specified. Of the various possibilities, hafnium oxide, hafnium silicate, or hafnium silicon oxynitride may be the most suitable replacement candidates for conventional gate dielectrics due to their excellent thermal stability at high temperatures.

Silicon metal oxide semiconductor field effect transistors (MOSFETs) fabricated with a hafnium-based dielectric as the gate dielectric suffer from a non-ideal threshold voltage when n-MOSFETs are fabricated. This is a general problem, and in particular, when the MOSFET consists of HfO₂ as the dielectric and TiN/polySi as the gate stack, the threshold voltage is in the 0.05 to 0.3 V range typically after standard thermal treatments. Ideally, the threshold voltage should be around −0.2 to −0.05 V or so.

One solution to the above mentioned problem is to form a capping layer containing at least one oxide of an electropositive metal on top of the high k gate dielectric material. By “electropositive” it is meant a metal that has an Allred-Rochow electronegativity of less than about 1.5.

The presence of the capping layer containing at least one electropositive metal oxide on such high k dielectric films allows one to tune the threshold voltage for high k based nMOSFETs. Such a technique is disclosed, for example, in U.S. Patent Application Publication No. 2006/0244035 A1 as well as in U.S. Patent Application Publication No. 2006/0289948 A1. In the '035 publication, a rare earth metal-containing layer such as La₂O₃ is disclosed as the capping layer, while in the '948 publication an alkaline earth metal layer such as MgO is disclosed as the capping layer.

FIG. 1 illustrates a typically nMOSFET which includes a capping layer as described in one of the aforementioned publications. The structure includes a semiconductor substrate 10 in which a portion thereof that is located directly beneath the gate stack serves as the device channel (labeled as 12 in FIG. 1). Atop the substrate is an interfacial layer 14 which typically comprises SiO₂. The presence of the interfacial layer 14 is to passivate the channel interface states and thus provide for adequate mobility for carriers (electrons or holes) in the channel 12. A high k gate dielectric 16 such as HfO₂ is located on top of the interfacial layer 14. The purpose of the high k gate dielectric 16 is to achieve the requisite capacitance of the gate stack, while maintaining sufficient distance between the substrate and the gate conductor (to be subsequently described) to reduce the leakage current between these two members during operation to an acceptable value. Atop the gate dielectric 16 is a capping layer 18. The capping layer 18 typically comprises an oxide of magnesium or lanthanum. The purpose of the capping layer 18 is to tune the threshold voltage for the device to the requisite value. A gate electrode 20 such as doped polysilicon or an elemental metal is present atop the capping layer 18. As is known to one skilled in the art, the gate electrode 20 makes electrical contact to the device.

Each of layers 14, 16 and 18 play a unique role in the proper function of the semiconductor device, as is discussed above. It is clear also from the structure that layers 14, 16 and 18 must be formed sequentially. It is therefore highly desirable that the method used to form each of layers 14, 16 and 18 not alter the thickness or chemical compositions of any of the previously layers formed.

One capping layer of particular interest is lanthanum oxide. In the prior art, this oxide along with many of the oxides used as a capping layer in the aforementioned structure is deposited by a physical vapor deposition (PVD) technique in which the oxide is formed by sputtering a metal such as lanthanum onto the high k gate dielectric, e.g., a layer of HfO₂, in the presence of oxygen.

PVD based depositions do not have the desirable characteristic of leaving the gate dielectric and the interfacial layers chemically and physically unaltered. This is because the metal arriving atop the dielectric layer is a powerful reducing agent, and thus has a tendency to reduce both the underlying gate dielectric as well as the interfacial layer. Since the metal of the capping layer is oxidized on the surface of the gate dielectric, the oxidation of the metallic species is a competitive process, between the oxygen arrival rate from the ambient oxygen, and the reduction of the underlying gate dielectric metal oxide and silicon oxide. As a result of this, the quality of the gate stack is degraded, and the mobility of carriers within the transistor is also negatively impacted.

In view of the above, there is an ongoing need for providing a new and improved method of forming an electropositive metal-containing capping layer that avoids the problems with PVD based techniques.

### BRIEF SUMMARY

The present invention provides a method of forming an electropositive metal-containing capping layer atop a stack of a high k gate dielectric/interfacial layer that avoids chemically and physically altering the high k gate dielectric and the interfacial layer.

As stated above, prior art PVD methods do not have the desirable characteristic of leaving the gate dielectric and the interfacial layers chemically and physically unaltered. This is because the metal arriving atop the dielectric layer is a powerful reducing agent, and thus has a tendency to reduce both the underlying gate dielectric as well as the interfacial layer. Since the metal of the capping layer is oxidized on the surface of the gate dielectric, the oxidation of the metallic species is a competitive process, between the oxygen arrival rate from the ambient oxygen, and the reduction of the underlying gate dielectric metal oxide and silicon oxide. As a result of this, the quality of the gate stack is degraded, and the mobility of carriers within the transistor is also negatively impacted.

To address the above, a chemical vapor deposition method is used in the present invention to form an electropositive metal-containing capping layer atop a stack of the high k gate dielectric and the interfacial layer. The electropositive metal used in the inventive CVD process is delivered onto the stack in a fully oxidized form and is thus not an effective reducing agent. Consequently, the electropositive metal-containing capping layer may be grown on the dielectric surface without perturbation to the underlying layers. Since oxygen is used to react away carbon present in the CVD precursor, it is essential that the growth occurs at low temperatures, typically 400° C. or below, so to avoid oxidizing the semiconductor substrate, and thus thickening the interfacial layer that is located on the substrate. The inventive method also achieves excellent uniformity of thickness across a substrate, which is required for consistent device threshold behavior.

In general terms, the method of the present invention comprises the step of:

positioning a substrate in a chemical vapor deposition reactor chamber, said substrate including a semiconductor substrate, an interfacial layer located on said semiconductor substrate, and a high k gate dielectric located on said interfacial layer;

evacuating said reactor chamber including said substrate to a base pressure of less than 1E-3 torr;

heating the substrate to a temperature of about 400° C. or less;

providing an electropositive metal-containing precursor to said reactor chamber; and

depositing an electropositive metal-containing capping layer onto said high k gate dielectric.

In a preferred embodiment of the present invention, the method includes the steps of:

positioning a substrate in a chemical vapor deposition reactor chamber, said substrate including a semiconductor substrate, an interfacial layer located on said semiconductor substrate, and a hafnium oxide located on said interfacial layer;

evacuating said reactor chamber including said substrate to a base pressure of less than 1E-3 torr;

heating the substrate to a temperature of about 400° C. or less;

providing a lanthanum-containing precursor to said reactor chamber; and

depositing a lanthanum oxide onto said hafnium oxide.

In addition to the method described above, the present invention also provides a semiconductor structure that is fabricated by the inventive method. In general terms, the semiconductor structure comprises:

a semiconductor substrate;

an interfacial layer having a first thickness located on a surface of said semiconductor substrate;

a high k gate dielectric located on a surface of said interfacial layer; and

a chemical vapor deposited electropositive metal-containing capping layer located directly on a surface of said high k gate dielectric, wherein said electropositive metal-containing capping layer has a thickness of about 3.0 nm or less and said first thickness of said interfacial layer is not altered by said chemical vapor deposited electropositive metal-containing capping layer.

### BRIEF DESCRIPTION OF THE SEVERAL VIEWS OF THE DRAWINGS

FIG. 1 is a pictorial representation (through a cross sectional view) of a prior art semiconductor structure including a gate stack located atop a semiconductor substrate.

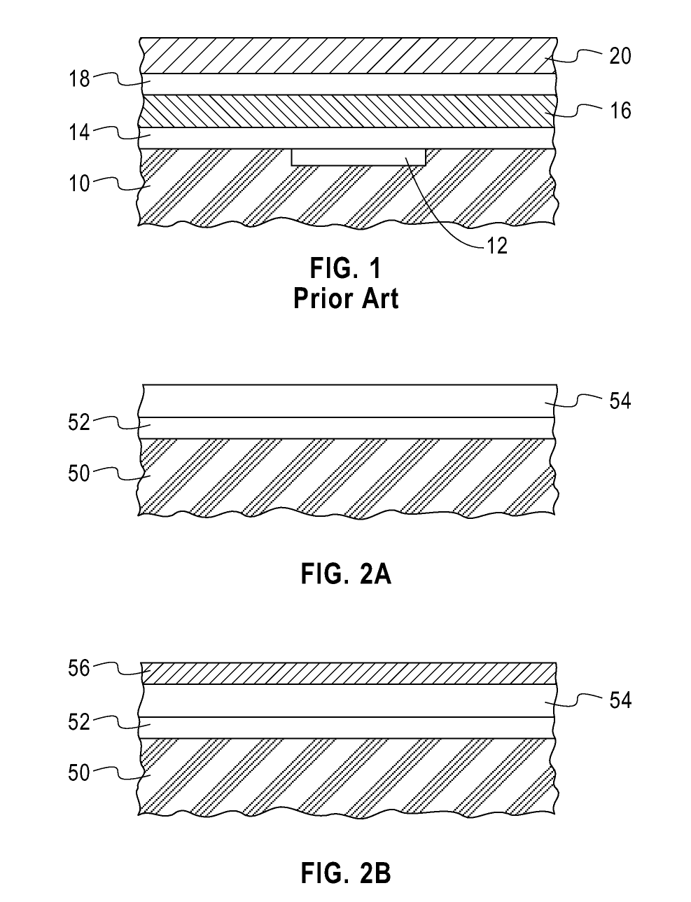

FIGS. 2A-2D are pictorial representations (through cross sectional views) illustrating the basic processing steps that are employed in the present invention.

FIGS. 3A-3B are pictorial representations (through cross sectional views) showing various structures that can contain the material stack shown in FIG. 2D.

FIG. 4 is a schematic diagram illustrating a reactor chamber used in the present invention for the chemical vapor deposition of an electropositive metal-containing capping layer on top of a high k gate dielectric.

### DETAILED DESCRIPTION

The present invention, which provides a deposition method for fabricating an electropositive metal-containing capping layer within a gate stack as well as the structure that is formed utilizing the inventive deposition method, will now be described in greater detail by referring to the following description and drawings that accompany the present application. It is noted that the drawings of the present application are provided for illustrative purposes only and, as such, the drawings are not drawn to scale.

In the following description, numerous specific details are set forth, such as particular structures, components, materials, dimensions, processing steps and techniques, in order to provide a thorough understanding of the present invention. However, it will be appreciated by one of ordinary skill in the art that the invention may be practiced without these specific details. In other instances, well-known structures or processing steps have not been described in detail in order to avoid obscuring the invention.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

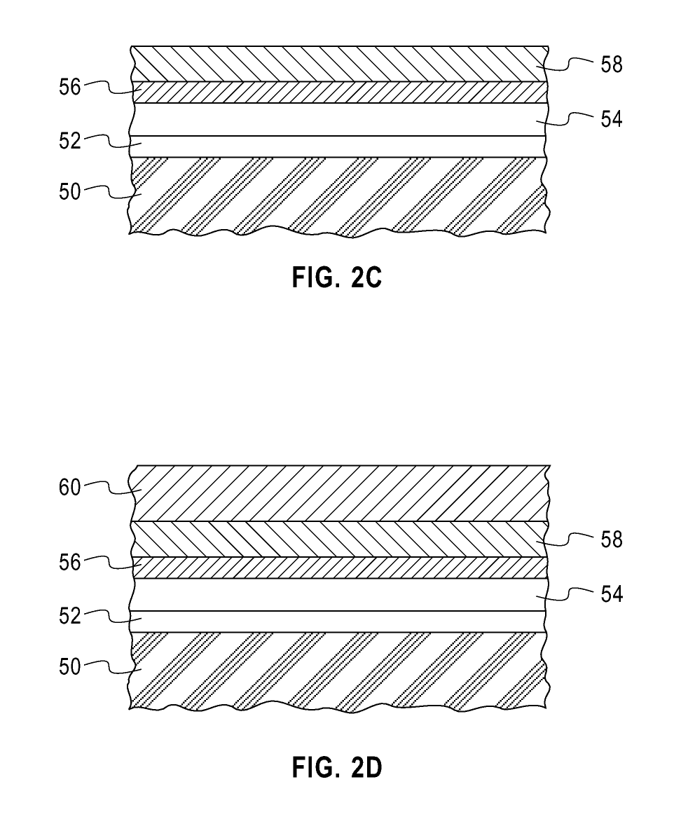

Reference is now made to FIGS. 2A-2D which are pictorial representations (through cross sectional views) depicting the basic processing steps that are used in forming the inventive gate stack on the surface of a semiconductor substrate. FIG. 2A shows an initial structure that is formed in the present invention that includes a semiconductor substrate 50, an interfacial layer 52 located on a surface of the semiconductor substrate 50 and a high k gate dielectric 54 that is located on the interfacial layer 52.

The semiconductor substrate 50 of the structure shown in FIG. 2A comprises any semiconducting material including, but not limited to: Si, Ge, SiGe, SiC, SiGeC, GaAs, GaN, InAs, InP and all other III/V or II/VI compound semiconductors. Semiconductor substrate 50 may also comprise an organic semiconductor or a layered semiconductor such as Si/SiGe, a silicon-on-insulator (SOI), a SiGe-on-insulator (SGOI) or a germanium-on-insulator (GOI). In some embodiments of the present invention, it is preferred that the semiconductor substrate 50 be composed of a Si-containing semiconductor material, i.e., a semiconductor material that includes silicon.

The semiconductor substrate 50 may be doped, undoped or contain doped and undoped regions therein. The semiconductor substrate 50 may include a single crystal orientation or it may include at least two coplanar surface regions that have different crystal orientations (the latter substrate is referred to in the art as a hybrid substrate). When a hybrid substrate is employed, the nFET is typically formed on a (100) crystal surface, while the pFET is typically formed on a (110) crystal plane. The hybrid substrate can be formed by techniques such as described, for example, in U.S. Patent Application Publication Nos. 2004/0256700 A1, 2005/0093104 A1, and 2005/0116290 A1, the entire contents of each are incorporated herein by reference.

The semiconductor substrate 50 may also include a first doped (n- or p-) region, and a second doped (n- or p-) region. For clarity, the doped regions are not specifically shown in the drawing of the present application. The first doped region and the second doped region may be the same, or they may have different conductivities and/or doping concentrations. These doped regions are known as “wells” and they are formed utilizing conventional ion implantation processes.

At least one isolation region (not shown) is then typically formed into the semiconductor substrate 50. The isolation region may be a trench isolation region or a field oxide isolation region. The trench isolation region is formed utilizing a conventional trench isolation process well known to those skilled in the art. For example, lithography, etching and filling of the trench with a trench dielectric may be used in forming the trench isolation region. Optionally, a liner may be formed in the trench prior to trench fill, a densification step may be performed after the trench fill and a planarization process may follow the trench fill as well. The field oxide may be formed utilizing a so-called local oxidation of silicon process. Note that the at least one isolation region provides isolation between neighboring gate regions, typically required when the neighboring gates have opposite conductivities, i.e., nFETs and pFETs. The neighboring gate regions can have the same conductivity (i.e., both n- or p-type), or alternatively they can have different conductivities (i.e., one n-type and the other p-type).

After processing the semiconductor substrate 50, an interfacial layer 52 is formed on the surface of the semiconductor substrate 50. The interfacial layer 52 is formed utilizing a conventional growing technique that is well known to those skilled in the art including, for example, oxidation or oxynitridation. When the substrate 50 is a Si-containing semiconductor, the interfacial layer 52 is comprised of silicon oxide, silicon oxynitride or a nitrided silicon oxide. When the substrate 50 is other than a Si-containing semiconductor, the interfacial layer 52 may comprise a semiconducting oxide, a semiconducting oxynitride or a nitrided semiconducting oxide. The thickness of the interfacial layer 52 is typically from about 0.5 to about 1.2 nm, with a thickness from about 0.8 to about 1 nm being more typical. The thickness, however, may be different after processing at higher temperatures, which are usually required during CMOS fabrication.

In accordance with an embodiment of the present invention, the interfacial layer 52 is a silicon oxide layer having a thickness from about 0.6 to about 0.8 nm that is formed by wet chemical oxidation. The process step for this wet chemical oxidation includes treating a cleaned semiconductor surface (such as a HF-last semiconductor surface) with a mixture of ammonium hydroxide, hydrogen peroxide and water (in a 1:1:5 ratio) at 65° C. Alternately, the interfacial layer 52 can also be formed by treating the HF-last semiconductor surface in ozonated aqueous solutions, with the ozone concentration usually varying from, but not limited to: 2 parts per million (ppm) to 40 ppm.

In yet another embodiment of the present invention, the interfacial layer 52 is a silicon oxide layer having a thickness from about 0.8 to about 1.4 nm that is formed by a rapid thermal oxidation (RTO) process or UV ozonation (UVO₂) at temperatures between 700°-100° C. In still another embodiment of the present invention, the interfacial layer 52 is a SiON layer wherein said chemical oxide or RTO or UVO₂ layer is nitrided by plasma nitridation or thermal nitridation by exposure to NO, N₂O and/or N₂ gases in process regimes known to those skilled in the art.

Next, a high k gate dielectric 54 can be formed on the surface of the interfacial layer 52 by a deposition process such as, for example, chemical vapor deposition (CVD), plasma-assisted CVD, physical vapor deposition (PVD), metalorganic chemical vapor deposition (MOCVD), atomic layer deposition (ALD), evaporation, reactive sputtering, chemical solution deposition and other like deposition processes. The high k gate dielectric 54 may also be formed utilizing any combination of the above processes.

The term “high k gate dielectric” as used herein refers to a dielectric material whose dielectric constant is greater than 4.0, preferably greater than 7.0. Examples of such high k gate dielectric materials include, but are not limited to TiO₂, Al₂O₃, ZrO₂, HfO₂, Ta₂O₅, La₂O₃, mixed metal oxides such a perovskite-type oxides, and combinations and multilayers thereof. Silicates and nitrides of the aforementioned metal oxides can also be used as the high k gate dielectric material.

The physical thickness of the high k gate dielectric 54 may vary, but typically, the high k gate dielectric 54 has a thickness from about 0.5 to about 10 nm, with a thickness from about 0.5 to about 3 nm being more typical.

In one highly preferred embodiment of the present invention the high k gate dielectric 54 is a Hf-based dielectric including one of hafnium oxide (HfO₂), hafnium silicate (HtSiOₓ), and Hf silicon oxynitride (HfSiON). In some embodiments, the Hf-based dielectric comprises a mixture of HfO₂ and ZrO₂. Typically, the Hf-based dielectric is hafnium oxide or hafnium silicate. The Hf-based dielectric is a “high k” material whose dielectric constant is greater than about 10.0.

In one embodiment of the present invention, the Hf-based dielectric is hafnium oxide that is formed by MOCVD were a flow rate of about 70 to about 90 mgm of hafnium-tetrabutoxide (a Hf-precursor) and a flow rate of O₂ of about 250 to about 350 seem are used. The deposition of Hf oxide occurs using a chamber pressure between 0.3 and 0.5 Torr and a substrate temperature of between 400° and 500° C.

In another embodiment of the present invention, the Hf-based dielectric is hafnium silicate which is formed by MOCVD using the following conditions (i) a flow rate of the precursor Hf-tetrabutoxide of between 70 and 90 mg/m, a flow rate of O₂ between 25 and 100 seem, and a flow rate of SiH₄ of between 20 and 60 seem; (ii) a chamber pressure between 0.3 and 0.5 Torr, and (iii) a substrate temperature between 400° and 500° C.

Once the structure shown in FIG. 2A is formed, an electropositive metal-containing capping layer 56 is then formed on the high k gate dielectric 54 providing the structure shown in FIG. 2B. Typically, the electropositive metal-containing capping layer 56 comprises at least one element from Group 2 (e.g., IIA), 3 (e.g., IIIA) and 13 (e.g., IIIB) of the Periodic Table of Elements. Examples of Group 2 elements that can be used in the present invention include Be, Mg, Ca, Sr and/or Ba. Examples of Group 13 elements that can be used in the present invention include B, Al, Ge, and/or In. Examples of Group 3 elements include, for example, Sc, Y, La, Ce, Pr, Nd, Pm, Sm, Eu, Ga, Th, Dy, Ho, Er, Tm, Yb, Lu or mixtures thereof.

In one highly preferred embodiment, the electropositive metal-containing capping layer 56 comprises an oxide or nitride of at least one element from Group 13 of the Periodic Table of Elements including, for example, La, Ce, Pr, Nd, Pm, Sm, Eu, Ga, Tb, Dy, Ho, Er, Tm, Yb, Lu or mixtures thereof. In this particular embodiment, it is most preferred that the electropositive metal-containing capping layer 56 comprises an oxide of La, Ce, Y, Sm, Er, and/or Tb, with La₂O₃ or LaN being most preferred.

In another highly preferred embodiment, the electropositive metal-containing capping layer 56 comprises an alkaline earth-metal containing oxide or nitride. Oxides are preferred over nitrides. Examples of alkaline earth metal-containing oxides that can be deposited in the present invention include, but are not limited to MgO, CaO, SrO and BaO. In one preferred embodiment of the present invention, the alkaline earth metal-containing compound includes Mg. MgO is a highly preferred alkaline earth metal-containing material employed in the present invention.

The electropositive metal-containing capping layer 56 typically has a deposited thickness from about 0.1 nm to about 3.0 nm, with a thickness from about 0.3 nm to about 1.0 nm being more typical.

Unlike the prior art in which PVD techniques are used in forming the electropositive metal-containing capping layer, the present invention employs a chemical vapor deposition (CVD) method for the formation of the electropositive metal-containing capping layer 56. The use of CVD as the deposition technique provides an electropositive metal-containing capping layer 56 that is ultra-thin (about 3.0 nm or less, preferably less than 1.0 nm), continuous (i.e., substantially no breaks within the deposited layer is observed) and has little or no thickness variation across a surface (e.g., a 200 mm diameter area). By ‘little or no’ thickness variation it is meant that the thickness across the deposited surface did not exceed 15% (in other words, a less than 15% thickness variation was observed using the CVD method described herein).

In addition to the aforementioned properties, applicants have determined that an electropositive metal-containing capping layer 56 that is deposited by CVD does not effect (chemically or physically) any of the layers in which it is formed there over. For example, CVD of the electropositive metal-containing capping layer 56 does not alter the thickness of the underlying interfacial layer 52. Since the underlying layers are not effected by CVD of the electropositive metal-containing capping layer 56, the mobility of the resultant device will be higher and the thickness of the underlying layers (i.e., interfacial layer and high k gate dielectric) remain at their deposited thickness. When a PVD technique is used, the underlying layers are effected; in particular, applicants have determined that when a PVD is employed the underlying interfacial layer is thinned to an undesirable thickness which effects (alters) the mobility of the resultant device in a negative way.

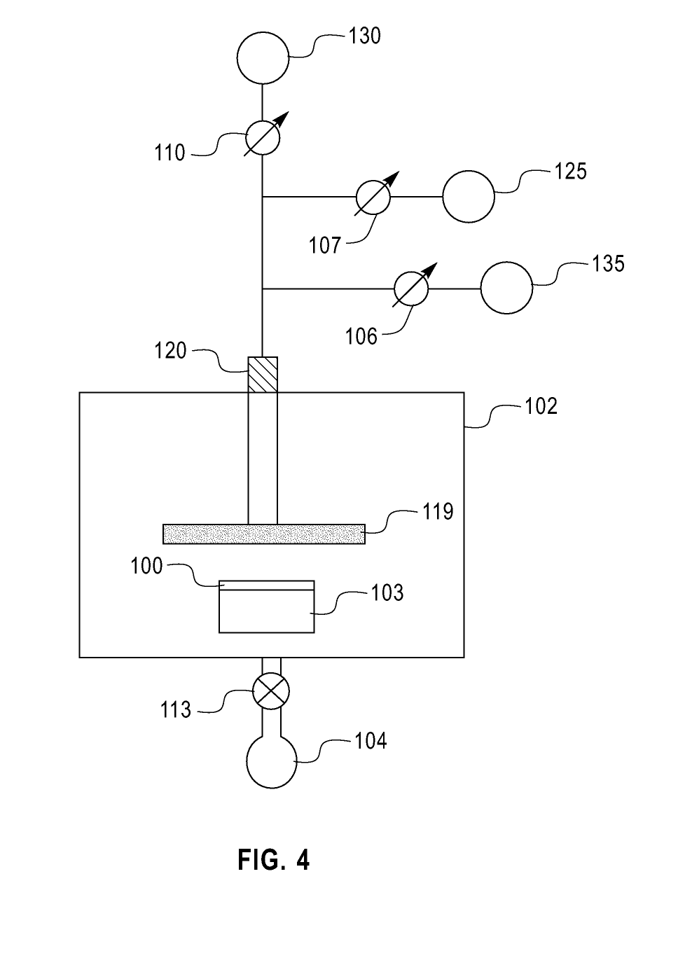

The CVD of an electropositive metal-containing capping layer 56 is now described in greater detail by referring to FIG. 4. Specifically, FIG. 4 is a schematic drawing of a CVD reactor chamber that can be used for the deposition of the electropositive metal-containing capping layer 56. A substrate 100 including materials 50, 52 and 54, for example, is placed in a vacuum chamber 102 atop a heater 103. The vacuum system is then evacuated to a pressure of less than 1E-3, or, preferably, less than 1E-5 torr and the substrate 100 is raised to a temperature from about 300° to about 400° C., with a temperature from about 325° to about 370° C. being more preferred. Simultaneously a liquid mass flow controller 107 and two gas phase mass flow controllers 106 and 110 are opened. The liquid mass flow 107 controller injects a solution of an electropositive metal-containing precursor dissolved in an organic solvent from the precursor supply vessel 125. The liquid is entrained in an inert gas (i.e., argon) flow from mass flow controller 110; reference numeral 130 denotes the inert gas supply vessel. The electropositive metal-containing precursor includes a compound or complex of one of the elements from Groups 2, 3 and 13 mentioned above and at least one ligand selected from the group consisting of a beta-diketonate, an alkoxide, an aryl, an alkyl and an amide, with a beta-diketonate and an alkoxide being highly preferred ligands. The solvent may be any convenient organic compound, which may be polar or non polar in nature. Examples of suitable solvents include, but are not limited to, alcohols, hydrocarbons, ethers, ketones and the like.

The term ‘beta-diketonate’ is used throughout the present application to mean not just the complex of a Group 2, 3 or 13 element with acetylacetone, 2,4-pentanedione, but also includes complexes with other beta-keto compounds including ethylacetylacetone, hexafluoropentanedione, 2,2,6,6-tetramethyl-3,5-heptanedione, 6,6,7,7,8,8,8,-heptafluoro-2,2-dimethyl-3,5-octanedione, 9-octadecynylacetylacetone, benzoylacetone, benzoyltrifluoracetone, 1,3-diphenyl-1,3-propanedione, methacryloxyacetylacetone, theonyltrifluoroacetone, trimethylacetylacetone, allylacetylacetone and methacryloxyethylacetylacetone.

The term “alkoxide” as used in the present invention denotes a conjugate base of an alcohol and therefore consists of an organic group bonded to a negatively charged oxygen atom. The alkoxide can be written as RO⁻, where R is an organic substituent typically including from about 1 to about 16 carbon, preferably 1 to 12 carbon atoms. The carbon atoms may be straight chain or branched. Examples of suitable alkoxides include methoxide, ethoxide, n-butoxide, s-butoxide, and t-butoxide.

The term “aryl” as used herein denotes any organic functional group or substituent thereof that is derived from at least one aromatic ring. The aromatic ring may include from about 4 to about 24, preferable 4 to 12, most preferably six carbon atoms. The most preferred aryl ligands include one of phenyl, benzyl, tolyl, and xylyl.

The term “alkyl” is used herein to denote a univalent (or free) radical containing only carbon and hydrogen atoms arranged in a chain. The chain may be a straight chain or branched. The alkyl may be unsubsituted or substituted with an organic functional group. The alkyl forms a homologous series with the general formula CₙH₂ₙ₊₁ in which n is typically from 1 to 16, preferably 2 to 12. Examples of suitable akyls include methyl, ethyl, butyl, and the like.

The term “amide” is used in the present invention to denote an organic functional group that is characterized by a carbonyl (C═O) linked to a nitrogen atom. The amide typically has the formula R—(C═O)—NR′R″ wherein R, R′ and R″ independently of each other include hydrogen and a hydrocarbon radical containing from 1 to 1, preferably 2 to 12 carbon atoms. Examples of amides that can be used in the present invention include ethanideamide and methanideamide.

Highly preferred electropositive metal-containing precursors that can be used in the present invention include, but are not limited to lanthanum tetramethylheptanedionate, and its tetraglyme adduct.

The precursor solution passes through a vaporizer assembly 120 and is directed onto the substrate 100 by means of a showerhead assembly 119. The gas phase mass flow controller 106 directs a flow of oxygen or nitrogen, preferably oxygen, into the showerhead assembly 119 and thus onto the substrate 100; in the drawing reference numeral 135 denotes the vessel including oxygen or nitrogen. The flow rates for the liquid mass flow controller are in the range from about 1E-3 to about 1E-1 cc/min, the flow of oxygen or nitrogen is in the range from about 10 to about 100 sccm, and the flow rate of the entraining inert gas is the range from about 100 to about 1000 sccm. During deposition the pressure in the reaction chamber is maintained constant at a value in the range from about 0.1 to about 10 torr by means of a pump 104, and an adjustable butterfly valve 113. Deposition is allowed to proceed until an electropositive metal-containing capping layer 56 of a requisite thickness is formed.

In a preferred embodiment of the invention, the high k dielectric 54 is comprised of hafnium oxide and the electropositive metal-containing capping layer 56 is comprised of lanthanum oxide.

Next, and as shown in FIG. 2C, an electrically conducting capping layer 58 is optionally formed on the surface of the electropositive metal-containing capping layer 56 utilizing a conventional deposition process. Examples of conventional depositions that can be used in forming the electrically conductive capping layer 58 include CVD, PVD, ALD, sputtering or evaporation. The electrically conductive capping layer 58 is formed on the surface of the electropositive metal-containing capping layer 56 utilizing a conventional deposition process in which the vacuum between depositions may or may not be broken.

The electrically conductive capping layer 58 comprises a metallic material and/or a semimetallic material that is capable of conducting electrons. Specifically, the capping layer 58 is a metallic capping layer such as a metal nitride or a metal silicon nitride. The electrically conductive capping layer 58 provides the functions of (a) protecting the electropositive metal-containing capping layer from the ambient, (b) acts a diffusion barrier to ambient oxygen, and (c) prevents reaction of the electropositive metal-containing layer with a Si-containing conductor. In the embodiment when the capping layer includes a metal, the metal component of the capping layer 58 may comprise a metal from Group 4 (e.g., IVB) or 5 (e.g., VB) of the Periodic Table of Elements (using CA nomenclature). Hence, the electrically conductive capping layer 58 may include Ti, Zr, Hf, V, Nb or Ta, with Ti or Ta being highly preferred. By way of example, the electrically conductive capping layer 58 preferably comprises TiN or TaN.

In addition to the aforementioned electrically conductive capping layer materials, the present invention also includes a ternary alloy of Ti—La—N, a ternary alloy of Ta—La—N or a stack of a ternary alloy of Ti—La—N or Ta—La—N that is mixed with La₂O₃ or another one of the above-mentioned materials used for the electropositive metal-containing layer. If the later is used, it may be possible to replace the separate electropositive metal-containing layer and the electrically conductive capping layer, with a single layer including both components.

The physical thickness of the electrically conductive capping layer 58 may vary, but typically, the electrically conductive capping layer 58 has a thickness from about 0.5 to about 200 nm, with a thickness from about 5 to about 80 nm being more typical.

In one embodiment of the present invention, the electrically conductive capping layer 58 is TiN that is deposited by evaporating Ti from an effusion cell held in the range of 1550° to 1900° C., typically 1600° to 1750° C., and using an atomic/excited beam of nitrogen that is passed through a remote radio frequency source. The substrate temperature can be around 300° C. and the nitrogen flow rate can be between 0.5 sccm and 3.0 sccm. These ranges are exemplary and by no way limit the present invention. The nitrogen flow rate depends upon the specifics of the deposition chamber, in particularly, the pumping rate on the chamber. The TiN may be deposited, in other ways, as well, such as chemical vapor deposition or sputtering and the technique is not critical.

Following the formation of the electrically conductive capping layer 58 as shown in FIG. 2C, a gate conductor 60 is formed atop the electrically conductive capping layer 58. The resultant structure including the gate conductor 60 is shown in FIG. 2D. Specifically, a blanket layer of a conductive material is formed on the electrically conductive capping layer 58 utilizing a known deposition process such as, for example, physical vapor deposition, CVD or evaporation. The conductive material used as the gate conductor 60 includes, but is not limited to Si-containing materials such as Si or a SiGe alloy layer in either single crystal, polycrystalline or amorphous form. The conductive material 60 may also be a conductive metal or a conductive metal alloy. Combinations of the aforementioned conductive materials are also contemplated herein. Si-containing materials are preferred as the gate conductor 60, with polySi being most preferred.

In addition to aforementioned conductive materials, the present invention also contemplates instances wherein the conductor 60 is fully silicided or a stack including a combination of a silicide and Si or SiGe. The silicide is made using a conventional silicidation process well known to those skilled in the art. Fully silicided gates can be formed using a conventional replacement gate process; the details of which are not critical to the practice of the present invention. The blanket layer of conductive gate material 60 may be doped or undoped. If doped, an in-situ doping deposition process may be employed in forming the same. Alternatively, a doped gate conductor can be formed by deposition, ion implantation and annealing. The ion implantation and annealing can occur prior to or after a subsequent etching step that patterns the material stack. The doping of the gate conductor 60 will shift the workfunction of the gate conductor formed. Illustrative examples of dopant ions for nMOSFETs include elements from Group VA of the Periodic Table of Elements (Group IIIA elements can be used when pMOSFETs are formed). The thickness, i.e., height, of the gate conductor 60 deposited at this point of the present invention may vary depending on the deposition process employed. Typically, the gate conductor 60 has a vertical thickness from about 20 to about 180 nm, with a thickness from about 40 to about 150 nm being more typical.

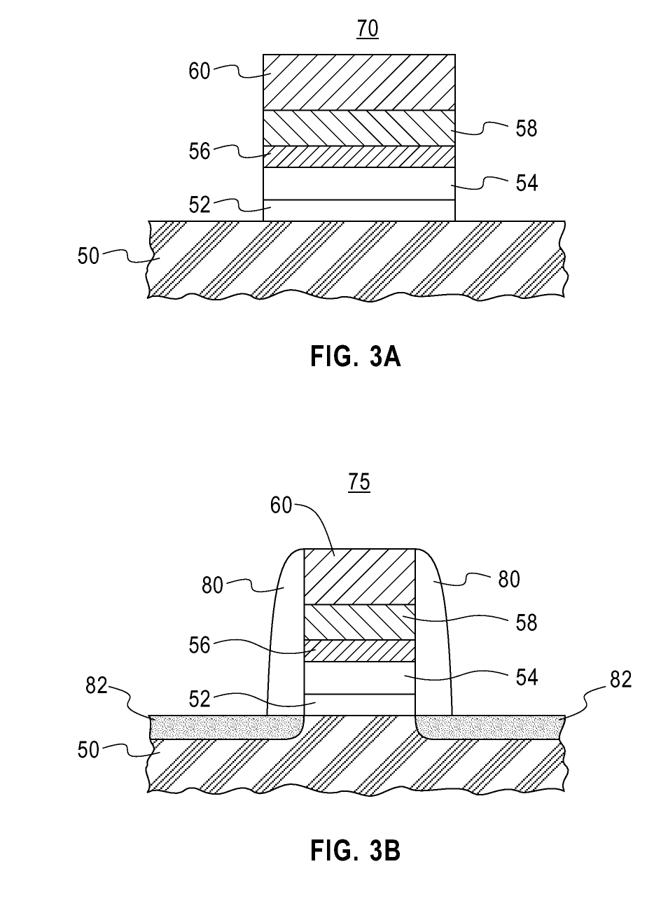

The material stack shown in FIG. 2D can be used be fabricated into a MOSCAP 70 as shown in FIG. 3A or a MOSFET 75 as shown in FIG. 3B utilizing conventional processes that are well known in the art. Each of the illustrated structures includes a material stack such as shown in FIG. 2D which has been at least patterned by lithography and etching.

The MOSCAP formation includes forming a thermal sacrificial oxide (not shown) on the surface of the semiconductor substrate. Using lithography, the active areas of the capacitor structure are opened in the field oxide by etching. Following the removal of the oxide, the material stack as shown in FIG. 2D is formed as described above. Specifically, the material stack was provided, patterned by lithography and etching, and then the dopants are introduced into the gate conductor 60. The dopants are typically P (implant dose of 5E15 ions/cm² using an implant energy of 12 keV). The dopants are activated using an activation anneal that is performed at 950° C. to 1000° C. for about 5 seconds. In some cases, a forming gas anneal (5-10% hydrogen) can follow which is performed between 500° to 550° C. for interfacial layer/semiconductor substrate interface state passivation.

The MOSFET formation includes first forming isolation regions, such as trench isolation regions, within the substrate as described above. A sacrificial oxide layer can be formed atop the substrate prior to formation of the isolation regions. Similar to the MOSCAP and after removing the sacrificial oxide, a material stack as described above is formed. Following patterning of the material stack, at least one spacer 80 is typically, but not always, formed on exposed sidewalls of each patterned material stack. The at least one spacer 80 is comprised of an insulator such as an oxide, nitride, oxynitride and/or any combination thereof. The at least one spacer 80 is formed by deposition and etching.

The width of the at least one spacer 80 must be sufficiently wide such that the source and drain silicide contacts (to be subsequently formed) do not encroach underneath the edges of the patterned material stack. Typically, the source/drain silicide does not encroach underneath the edges of the patterned material stack when the at least one spacer 80 has a width, as measured at the bottom, from about 20 to about 80 nm.

The patterned material stack can also be passivated at this point of the present invention by subjecting the same to a thermal oxidation, nitridation or oxynitridation process. The passivation step forms a thin layer of passivating material about the material stack. This step may be used instead or in conjunction with the previous step of spacer formation. When used with the spacer formation step, spacer formation occurs after the material stack passivation process.

Source/drain diffusion regions 82 are then formed into the substrate. The source/drain diffusion regions 82 are formed utilizing ion implantation and an annealing step. The annealing step serves to activate the dopants that were implanted by the previous implant step. The conditions for the ion implantation and annealing are well known to those skilled in the art. The source/drain diffusion regions 82 may also include extension implant regions which are formed prior to source/drain implantation using a conventional extension implant. The extension implant may be followed by an activation anneal, or alternatively the dopants implanted during the extension implant and the source/drain implant can be activated using the same activation anneal cycle. Halo implants are also contemplated herein.

In some cases, a forming gas anneal (5-10% hydrogen) can follow which is performed between 450° to 550° C. for interfacial layer/semiconductor substrate interface state passivation.

The above processing steps form the structure shown in FIG. 3B. Further CMOS processing such as formation of silicided contacts (source/drain and gate) as well as formation of BEOL (back-end-of-the-line) interconnect levels with metal interconnects can be formed utilizing processing steps that are well known to those skilled in the art.

The following example is provided for illustrative purposes and thus it should not be construed to limit the scope of the present application in any way.

### EXAMPLE

In this example, a material stack comprising a Si substrate, a silicon oxide interfacial layer, a hafnium oxide gate dielectric, a lanthanum oxide electropositive metal-containing layer, a TiN electrically conductive capping layer and a Si-containing conductor was prepared. The lanthanum oxide was prepared utilizing the CVD method mentioned above. Specifically, a lanthanum oxide precursor comprised of lanthanum tetramethylheptanedionate which was dissolved in a solvent selected from the group of toluene and n-octane was employed. The substrate including a semiconductor substrate 50 comprising Si, an interfacial layer 52 comprising an oxide of silicon, and a high k gate dielectric 54 comprising hafnium oxide was placed in the reactor chamber mentioned above, which was thereafter evacuated to a pressure of less than 1E-5 torr, and heated to 400° C. The liquid precursor solution was injected into the vaporizer at the rate of 0.02 cc/min, and entrained in a flow of 300 sccm of Ar. The vaporizer was maintained at a temperature between 160°-190° C. The process was independent of vaporizer temperature over this range. During the deposition the reaction chamber temperature was maintained at 800 mtorr. Under these conditions a growth rate of approximately 0.1 nm/min was maintained. It is understood that the specific conditions given above are appropriate to establish the requisite conditions in a specific reactor, and are thus intended for guidance only. Reactors with differing volumes, pumping speeds etc. might require significant deviations from the specific flows and pressures given above.

TEM (not shown) and the resultant analysis show that the lanthanum stayed in the hafnium oxide and that the silicon oxide interfacial layer remained untouched. Moreover, thinning of the interfacial layer was not observed.

Applicants have also determined that a threshold voltage lowering with an increase in the thickness of the CVD lanthanum oxide electropositive metal-containing capping layer was not observed while such a lowering in threshold voltage was observed when the electropositive metal-containing capping layer was deposited by a PVD technique thereby making the threshold voltage shift insensitive to small changes in the capping layer thickness, and making it more manufacturable. The applicants also observed that a CVD electropositive metal-containing layer had better mobility than the corresponding PVD electropositive metal-containing layer at the same Tᵢₙᵥ.

While the present invention has been particularly shown and described with respect to preferred embodiments thereof, it will be understood by those skilled in the art that the foregoing and other changes in forms and details may be made without departing from the spirit and scope of the present invention. It is therefore intended that the present invention not be limited to the exact forms and details described and illustrated, but fall within the scope of the appended claims.

What is claimed is:

1. A semiconductor structure comprising:
a semiconductor substrate;
an interfacial layer having a first thickness located on a surface of said semiconductor substrate;
a high k gate dielectric located on a surface of said interfacial layer; and
a chemical vapor deposited electropositive metal-containing capping layer located directly on a surface of said high k gate dielectric, wherein said electropositive metal-containing capping layer has a thickness of about 3.0 nm or less and said first thickness of said interfacial layer is not altered by said chemical vapor deposited electropositive metal-containing capping layer.

2. The semiconductor structure of claim 1 further comprising an electrically conductive cap layer atop the electropositive metal-containing capping layer.

3. The semiconductor structure of claim 2 further comprising a gate conductor atop the electrically conductive cap layer.

4. The semiconductor structure of claim 1 further comprising a gate conductor atop the electropositive metal-containing capping layer.

5. The semiconductor structure of claim 1 wherein said electropositive metal-containing capping layer is an oxide or nitride of an element from Group 2, 3 or 13 of the Periodic of Elements.

6. The semiconductor structure of claim 1 wherein said electropositive metal-containing capping layer is lanthanum oxide or magnesium oxide.

7. The semiconductor structure of claim 1 wherein said high k gate dielectric is hafnium oxide and said electropositive metal-containing capping layer is lanthanum oxide.
